(19) United States
(12) Patent Application Publication
(10) Pub. No.: US 2013/0207144 A1
(43) Pub. Date: Aug. 15, 2013

(54) COMPONENT AND METHOD FOR PRODUCING A COMPONENT

(71) Applicants: Johann Ramchen, Altdorf (DE); Jörg Erich Sorg, Regensburg (DE); Simon Jerebic, Tegernheim (DE); Bert Braune, Wenzenbach (DE)

(72) Inventors: Johann Ramchen, Altdorf (DE); Jörg Erich Sorg, Regensburg (DE); Simon Jerebic, Tegernheim (DE); Bert Braune, Wenzenbach (DE)

(73) Assignee: OSRAM Opto Semiconductors GmbH, Regensburg (DE)

(21) Appl. No.: 13/808,705

(22) PCT Filed: Jul. 1, 2011
(86) PCT No.: PCT/EP2011/061133

§ 371 Date: Mar. 13, 2013

(30) Foreign Application Priority Data
Jul. 7, 2010 (DE) 102010026343.5

(51) Int. Cl. H01L 33/52; H01L 31/18; H01L 31/0203

(52) U.S. Cl. CPC H01L 33/52; H01L 31/0203; H01L 31/18
USPC 257/98; 257/432; 438/26; 438/64

(57) ABSTRACT

A component with an optoelectronic semiconductor chip fixed to a connection carrier by a bonding layer and embedded in an encapsulation, wherein a decoupling layer is arranged at least in places between the bonding layer and the encapsulation.

### RELATED APPLICATIONS

This is a §371 of International Application No. PCT/EP2011/061133, with an international filing date of Jul. 1, 2011 (WO 2012/004202 A1, published Jan.12, 2012), which is based on German Patent Application No. 10 2010 026 343.5, filed Jul. 7, 2010, the subject matter of which is incorporated herein by reference.

### TECHNICAL FIELD

This disclosure relates to a component with an optoelectronic semiconductor chip and to a method for producing such a component.

### BACKGROUND

To produce surface-mountable optoelectronic components such as, for example, surface-mountable light-emitting diodes, semiconductor chips may be fixed in a housing and provided with an encapsulation to protect the semiconductor chip.

Mechanical stresses may cause detachment of the semiconductor chip, which may lead to premature failure of the component.

It could therefore be helpful to provide a component which is more reliable when in operation and a method with which such a component may be simply and reliably produced.

### SUMMARY

We provide a component with an optoelectronic semiconductor chip fixed to a connection carrier by a bonding layer and embedded in an encapsulation, wherein a decoupling layer is arranged at least in places between the bonding layer and the encapsulation.

We also provide a method of producing a component with an optoelectronic semiconductor chip including providing a connection carrier, fixing the semiconductor chip to the connection carrier with a bonding layer, applying a decoupling layer to the bonding layer, and applying an encapsulation to the decoupling layer, wherein the semiconductor chip is embedded in the encapsulation.

We further provide a component with an optoelectronic semiconductor chip fixed to a connection carrier by a bonding layer and embedded in an encapsulation, wherein a decoupling layer is arranged at least in places between the bonding layer and the encapsulation, the decoupling layer has a modulus of elasticity of at most 1 GPa, and the semiconductor chip projects beyond the decoupling layer in a vertical direction.

### BRIEF DESCRIPTION OF THE DRAWINGS

FIG. 1 is a schematic sectional view of a first example of a component.

FIG. 2 is a schematic sectional view of a second example of a component.

FIG. 3 shows an example of an optoelectronic semiconductor chip for a component.

FIGS. 4A to 4C show an example of as method for producing a component by intermediate steps shown in each case in schematic sectional view.

### DETAILED DESCRIPTION

Our component comprises an optoelectronic semiconductor chip fixed to a connection carrier by a bonding layer and embedded in an encapsulation. A decoupling layer is arranged at least in places between the bonding layer and the encapsulation.

The decoupling layer decouples the bonding layer and the encapsulation mechanically from one another. The risk of mechanical stresses, in particular tensile stresses, in the component resulting in detachment of the semiconductor chip is greatly reduced thereby. The decoupling layer is thus configured such that stresses arising in the encapsulation are not transferred to the bonding layer or are transferred only to a reduced extent.

In a plan view of the component, the encapsulation may in particular completely overlap the decoupling layer.

Furthermore, the decoupling layer lowers the elasticity requirements of the encapsulation. A material may therefore be used for the encapsulation which has a comparatively high modulus of elasticity, without the mechanical stability of the bond between semiconductor chip and connection carrier thereby being on at risk. The encapsulation may, for example, contain an epoxide with a modulus of elasticity of 2 GPa or more.

The decoupling layer preferably exhibits a lower modulus of elasticity than the encapsulation. The lower the modulus of elasticity, the lower the resistance of a material to deformation.

The material for the decoupling layer preferably exhibits a modulus of elasticity of at most 1 GPa, particularly preferably of at most 200 kPa.

Preferably, the decoupling layer contains a material, the glass transition temperature T_{G} of which is room temperature or lower. At temperatures above the glass transition temperature, organic or inorganic glasses find themselves in an energy-elastic range in which they are distinguished by high deformability. The decoupling layer preferably contains a material from the material group consisting of elastomer, resin, silicone resin, silicone, silicone gel, polyurethane and rubber.

Preferably, particles are embedded in the decoupling layer. The particles allow the density of the decoupling layer to be increased. This may mean that the decoupling layer has less thermal effect. The risk of stresses being transferred to the bonding layer is reduced to a greater extent thereby.

Furthermore, the particles allow the optical properties of the decoupling layer to be adjusted.

The decoupling layer may be configured to be reflective for the radiation generated or to be detected by the semiconductor chip when in operation. In that case, particles may be embedded in the decoupling layer which reflect the radiation, in particular diffusely. For example, by adding titanium dioxide particles it is possible to achieve a reflectivity in the visible spectral range of 85% or more, for example, 95%.

Alternatively, the decoupling layer is configured to absorb in a targeted manner the radiation emitted by the semiconductor chip when the latter is in operation. “Absorb in a targeted manner” is in particular understood to mean that at least 80% of the radiation is absorbed when it impinges on the decoupling layer.

In particular, the decoupling layer may be black to the human eye. With such a decoupling layer, an increased contrast may be achieved between the “off” state and “on” state in a radiation-emitting component. Carbon black particles are, for example, suitable for an absorbing decoupling layer.

Preferably, in a plan view of the component, the decoupling layer at least partially, preferably completely, overlaps a part of the bonding layer which projects beyond the semiconductor chip. Complete overlap ensures that the encapsulation and the bonding layer are not directly adjacent one another at any point of the component.

Further preferably, the decoupling layer directly adjoins the semiconductor chip. In particular, the decoupling layer may surround the semiconductor chip in the lateral direction, i.e., in a direction extending along a main plane of extension of the semiconductor layers of the optoelectronic semiconductor chip.

The component preferably takes the form of a surface-mountable component (surface mounted device, SMD). The component further comprises a housing body. The housing body may comprise a cavity in which the semiconductor chip is arranged. In addition, the connection carrier may take the form of part of a lead frame onto which a main body of the housing body may be molded.

Preferably, in a plan view of the component, a bottom face of the cavity is completely covered by the decoupling layer. In other words, a side face of the cavity adjoining the bottom face may bound the decoupling layer in the lateral direction.

Further preferably, the semiconductor chip projects beyond the decoupling layer in a vertical direction. This ensures in a simple way that a top portion of the semiconductor chip remote from the connection carrier is free of the decoupling layer.

In a method for producing a component with an optoelectronic semiconductor chip, a connection carrier may be provided. The semiconductor chip may be fixed to the connection carrier by a bonding layer. A decoupling layer is applied to the bonding layer. An encapsulation is applied to the decoupling layer, the semiconductor chip being embedded in the encapsulation.

The encapsulation may be applied such that, with the decoupling layer, mechanical stresses in the component cannot or at least cannot significantly endanger the bond between the semiconductor chip and the connection carrier.

Preferably, the decoupling layer is applied by a dispenser. Alternatively or in addition, another metering and filling method can be used, for example, casting, injection molding, transfer molding or printing.

The above-described method is particularly suitable for producing a component described further above. Features listed in connection with the component may therefore also be used for the method and vice versa.

Further features, configurations and convenient aspects are revealed by the following description of the examples in conjunction with the figures.

Identical, similar or identically acting elements are provided with the same reference numerals in the figures.

The figures and the size ratios of the elements illustrated in the figures relative to one another are not to be regarded as being to scale. Rather, individual elements may be illustrated on an exaggeratedly large scale for greater ease of depiction and/or better comprehension.

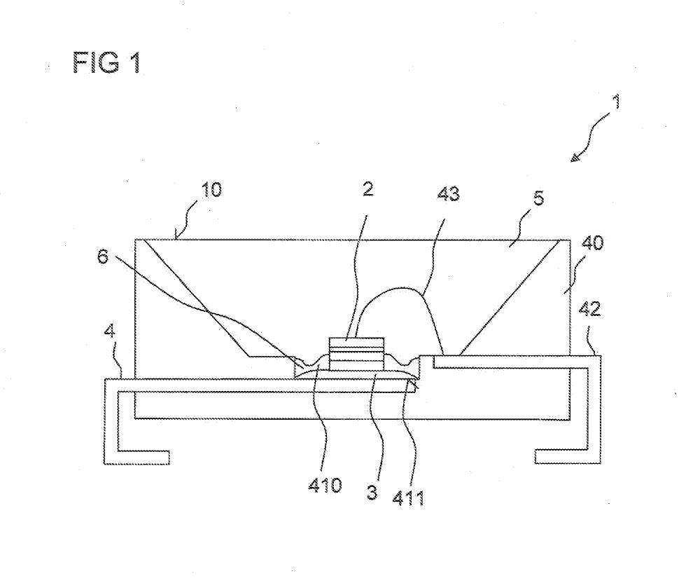

A first example of a component is shown in schematic sectional view in FIG. 1. The component 1 comprises an optoelectronic semiconductor chip 2, which is fixed to a connection carrier 4 by a bonding layer 3. An adhesive layer is particularly suitable for the bonding layer 3, but a solder layer may also be used.

The connection carrier 4 and a further connection carrier 42 form a lead frame for the optoelectronic component 1. A housing body 40 is molded onto the lead frame.

By way of example, the component 1 takes the form of a surface-mountable component which is electrically contactable externally from the side remote from the radiation passage face 10 by the connection carrier 4 and the further connection carrier 42.

The housing body 40 comprises a cavity 410 in which the semiconductor chip 2 is arranged. The further connecting conductor 42 connects by a connecting line 43, for instance a wire bond connection, to the semiconductor chip 2 such that when the component is in operation, charge carriers can be injected into the semiconductor chip 2 or flow out of the semiconductor chip on different sides via the connection carrier 4 and the further connection carrier 42.

The semiconductor chip 2 and the connecting line 43 are embedded in an encapsulation 5, which protects the semiconductor chip and the connecting line from external influences such as mechanical loading or moisture.

The encapsulation 5 forms a radiation passage face 10 for the component.

A decoupling layer 6 is arranged between the encapsulation 5 and the bonding layer 3. In a plan view of the component, the decoupling layer 6 covers that part of the bonding layer 3 which projects in a lateral direction, i.e., along a main plane of extension of the semiconductor layers of the semiconductor chip 2, beyond the semiconductor chip 2. The encapsulation 5 and the bonding layer 3 thus do not directly adjoin each other at any point. In this way mechanical decoupling between the bonding layer and the encapsulation is reliably achieved.

The encapsulation 5 overlaps the decoupling layer 6 completely in plan view onto the component 1.

The decoupling layer 6 exhibits a lower modulus of elasticity than the encapsulation. Mechanical stresses in the component 1 thus have only a reduced effect on the bonding layer 3. The risk of detachment of the semiconductor chip 2 from the connection carrier 4, for instance at a boundary surface between the connection carrier and the bonding layer 3, is thus greatly reduced.

The decoupling layer 6 preferably exhibits a modulus of elasticity of at most 1 GPa, particularly preferably of at most 200 kPa.

Preferably, the decoupling layer contains a material, the glass transition temperature T_{G} of which is room temperature or lower. The decoupling layer preferably contains a material from the material group consisting of elastomer, resin, silicone resin, silicone, silicone gel, polyurethane and rubber.

Due to the mechanical decoupling produced by the decoupling layer 6, a material with a comparatively high modulus of elasticity, for example, 2 GPa or more may also be used for the encapsulation 5. For example, the encapsulation may contain an epoxide or consist of an epoxide.

The semiconductor chip 2 projects beyond the decoupling layer 6 in the vertical direction. A surface of the semiconductor chip 2 remote from the connection carrier 4 thus remains free of the decoupling layer 6.

The semiconductor chip 2, in particular an active region provided for the emission and/or detection of radiation, preferably contains a III-V compound semiconductor material.

III-V semiconductor materials are particularly suitable for producing radiation in the ultraviolet (AlₓIn_{y}Ga_{1-x-y}N) through the visible (AlₓIn_{y}Ga_{1-x-y}N, in particular for blue to green radiation, or AlₓIn_{y}Ga_{1-x-y}P, in particular for yellow to red radiation) as far as into the infrared (AlₓIn_{y}Ga_{1-x-y}As) range of the spectrum. In each case 0≦x≦1, 0≦y≦1 and x+y≦1 applies, in particular with x≠1, y≠1, x≠0 and/or y≠0. Using III-V semiconductor materials, in particular from the stated material systems, it is additionally possible to achieve high internal quantum efficiencies in the generation of radiation.

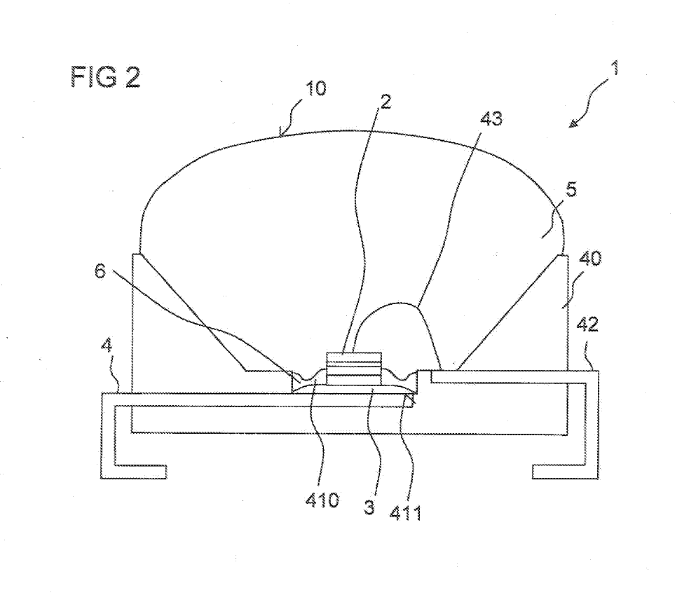

A second example of a component is illustrated in schematic sectional view in FIG. 2. This second example substantially corresponds to the first example described in connection with FIG. 1. Unlike in FIG. 1, the encapsulation 5 is convexly curved on the side remote from the semiconductor chip 2, in a plan view of the component, in this example the encapsulation 5 additionally fulfils the function of a convergent lens for the radiation emitted and/or to be received by the semiconductor chip when in operation. The encapsulation may here be of single- or multi-part construction. For example, a region of the encapsulation forming the lens is formed in a separate production step after encapsulation of the semiconductor chip.

The spatial radiation pattern of the component 1 is adjustable by the shape of the encapsulation 5 on the radiation passage face 10 side.

Furthermore, unlike in the first example particles 65 are embedded in the decoupling layer 6. The particles allow the density of the decoupling layer to be adjusted, in particular increased. In this way, the thermal expansion of the decoupling layer may be simply reduced.

The particles 65 preferably have an average size of 200 nm to 10 μm, particularly preferably 500 nm to 5 μm.

The particles may, for example, contain a glass or an oxide, for instance aluminium oxide, silicon oxide or titanium dioxide, or consist of such a material.

Furthermore, the particles may influence the optical properties of the decoupling layer.

Reflective particles may be embedded in the decoupling layer 6: Titanium dioxide particles, for example, allow reflectivities to be achieved in the visible spectral range of 85% or more, for example, 95%. A decoupling layer of reflective construction allows the total radiant power emerging from the component 1 to be increased.

Alternatively, particles may be embedded in the decoupling layer which absorb the radiation in targeted manner. Carbon black particles are an example of particles suitable for this purpose.

A decoupling layer 6 configured to absorb in targeted manner may increase the contrast ratio of the component 1 between the “off” and “on” states.

It goes without saving that the particles may also be used in the first example described in relation to FIG. 1. The particles may, however, also be omitted, depending on the requirements made of the decoupling layer 6.

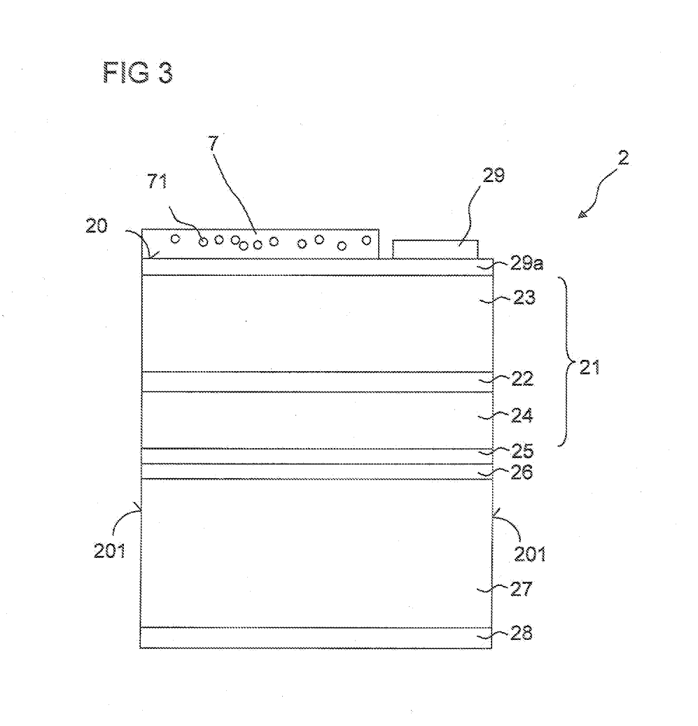

One example of a semiconductor chip 2, which is particularly suitable for a component according to the first or second example, is shown in schematic sectional view in FIG. 3.

The semiconductor chip 2 comprises a semiconductor body 21, with a semiconductor layer sequence which forms the semiconductor body. The semiconductor body 21 is arranged on a carrier 27 which differs from a growth substrate for the semiconductor layers of the semiconductor body 21. The carrier serves in mechanical stabilization of the semiconductor body 21. The growth substrate is no longer needed for this purpose. A semiconductor chip from which the growth substrate has been removed is also known as a thin-film semiconductor chip.

A thin-film semiconductor chip, for instance a thin-film light-emitting diode chip, may furthermore be distinguished by at least one of the following characteristic features:
on a first major surface, facing a carrier element, e.g., the carrier 27, of a semiconductor body comprising a semiconductor layer sequence with an active region, in particular of an epitaxial layer sequence, a mirror layer is applied or formed, for instance integrated as a Bragg mirror in the semiconductor layer sequence, the mirror layer reflecting back into the semiconductor layer sequence at least some of the radiation generated in the sequence;
the semiconductor layer sequence has a thickness of 20 μm or less, in particular 10 μm; and/or
the semiconductor layer sequence contains at least one semiconductor layer with at least one face which comprises an intermixing structure, which ideally leads to an approximately ergodic distribution of the light in the semiconductor layer sequence, i.e., it exhibits scattering behavior which is as ergodically stochastic as possible.

The basic principle of a thin-film light-emitting diode chip is described, for example, in I. Schnitzer et al., Appl. Phys. Lett. 63 (16), 18 Oct. 1993, 2174-2176, the subject matter of which is hereby incorporated by reference.

The semiconductor body 21 comprises an active region 22 arranged between a first semiconductor region 23 and a second semiconductor region 24. The first semiconductor region 23 and the second semiconductor region 24 are of mutually different conduction types, resulting in a diode structure.

The semiconductor body 21 is fixed to the carrier 27 by a mounting layer 26. A solder or an adhesive is, for example, suitable for the mounting layer.

Between the semiconductor body 21 and the carrier 27 there is arranged a mirror layer 25 provided to reflect radiation generated in the active region 22 when in operation towards a radiation exit face 20 of the semiconductor body.

When the semiconductor chip 2 is in operation, charge carriers are injected into the active region 22 from different sides via a first contact 28 and a second contact 29. A spreading layer 29a is formed between the second contact 29 and the semiconductor body 21. The spreading layer is provided for uniform injection of charge carriers into the active region The spreading, layer 29a may, for example, contain a transparent conductive oxide (TCO) or consist of such a material. As an alternative or in addition, the spreading layer 29a may comprise a metal layer, which is so thin that it is transparent or at least translucent to the radiation generated in the active region 22. If the electrical transverse conductivity of the first semiconductor region 23 is sufficiently high, it is however also possible to dispense with the spreading layer 29a.

A preferably premanufactured conversion plate 7 is formed on the radiation exit face 20 of the semiconductor body 21, in which plate a conversion material 71 is embedded for conversion of the radiation generated in the active region 22. The conversion plate may be fixed to the semiconductor body 21 by a fixing layer (not shown explicitly). At variance with the above, the conversion material 71 may also be embedded in the encapsulation 5. In the case in particular of direct utilization of the primary radiation emitted by the semiconductor chip, a conversion material may also be omitted completely.

Furthermore, at valiance with the described example, a semiconductor chip may also be used in which the carrier 27 is formed by the growth substrate for the semiconductor layer sequence of the semiconductor body.

In this case, the mounting layer 26 is not required. Furthermore, a semiconductor chip may also be used in which at least two contacts are arranged on the same side of the semiconductor chip.

Alternatively or in addition, the semiconductor chip may also take the form of a radiation detector for receiving radiation.

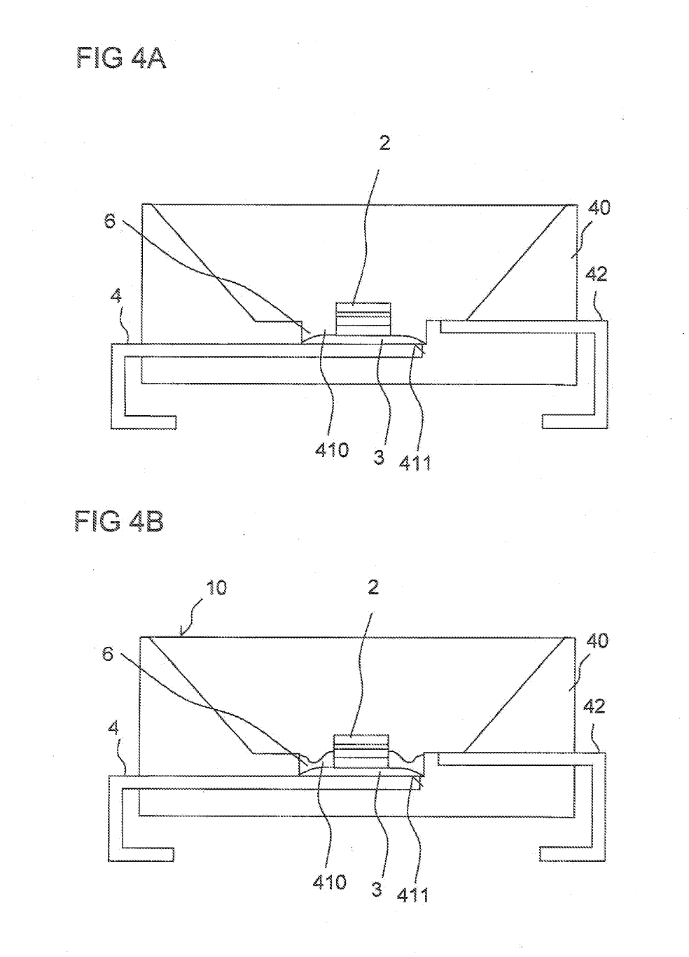

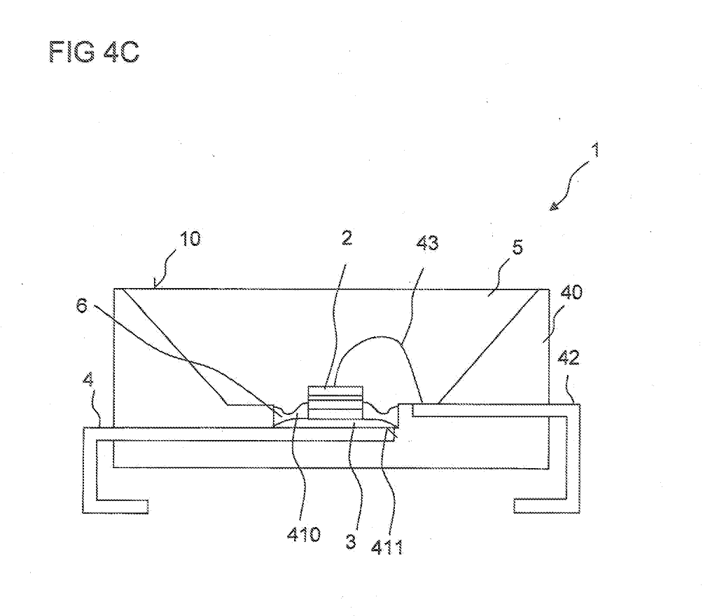

One example of a method for producing a component is shown by way of example in FIGS. 4A to 4C, for producing a component constructed as described in connection with FIG. 1.

A housing body 40 with a connection carrier 4 and a further connection carrier 42 is provided. The housing body 40 comprises a cavity 410 provided for mounting a semiconductor chip.

The semiconductor chip 2 is fixed to the connection carrier 4 by a bonding layer 3, for example, an electrically conductive adhesive layer or a solder layer.

As shown in FIG. 4B, a decoupling layer is applied to the bonding layer 3 in the region which projects laterally beyond the semiconductor chip 2. This may proceed, for example, by a dispenser. Alternatively casting, injection molding, transfer molding or printing may be used.

To produce an electrically conductive connection of the semiconductor chip 2 with the further connection carrier 42, a bonding wire connection is formed as a connecting line 43 between the semiconductor chip 2 and the further connection carrier (FIG. 4C). At variance with the described example, the connecting line 43 may however also be formed before the decoupling layer is applied.

To produce the component, the semiconductor chip 2 and the connecting line 43 are embedded in an encapsulation 5. The encapsulation 5 is decoupled mechanically from the bonding layer 3 by the decoupling layer 6. The risk of mechanical stresses which arise causing detachment of the semiconductor chip 2 from the connection carrier 40 is thus greatly reduced. The service life and reliability of the component is thus increased.

The above-described method may produce components which are highly reliable and have a long service life even in the case of an encapsulation with a comparatively high modulus of elasticity, for example, an encapsulation based on an epoxide. The material for the encapsulation 5 does not therefore have to be selected primarily in terms of modulus of elasticity, but rather may be selected on the basis of other chemical and/or physical properties, for instance optical transparency or ageing resistance.

Our components and methods are not restricted by the description given with reference to the examples. Rather, this disclosure encompasses any novel feature and any combination of features, including in particular any combination of features in the appended claims, even if the feature or combination is not itself explicitly indicated in the claims or the examples.

1. A component with an optoelectronic semiconductor chip fixed to a connection carrier by a bonding layer and embedded in an encapsulation, wherein a decoupling layer is arranged at least in places between the bonding layer and the encapsulation.

2. The component according to claim 1, wherein the decoupling layer has a lower modulus of elasticity than the encapsulation.

3. The component according to claim 1, wherein the decoupling layer has a modulus of elasticity of at most 1 GPa,

4. The component according to claim 1, wherein particles are embedded in the decoupling layer.

5. The component according to claim 1, wherein the decoupling layer is configured to be reflective for the radiation generated or to be detected by the semiconductor chip when in operation.

6. The component according to claim 1, wherein the decoupling layer is configured to absorb in targeted manner the radiation emitted or to be detected by the semiconductor chip when in operation.

7. The component according to claim 1, wherein, in a plan view of the component, the decoupling layer completely overlaps a part of the bonding layer which projects beyond the semiconductor chip.

8. The component according to claim 1, wherein the decoupling layer directly adjoins the semiconductor chip.

9. The component according to claim 1, wherein the semiconductor chip projects beyond the decoupling layer in a vertical direction.

10. The component according to claim 1, further comprising a housing body, wherein the semiconductor chip is arranged in a cavity of the housing body.

11. The component according to claim 10, wherein a bottom face of the cavity is completely covered by the decoupling layer.

12. The component according to claim 1, wherein the decoupling layer contains a material, the glass transition temperature of which is room temperature or lower.

13. A method of producing a component with an optoelectronic semiconductor chip comprising:
providing a connection carrier;
fixing the semiconductor chip to the connection carrier with a bonding layer;
applying a decoupling layer to the bonding layer; and
applying an encapsulation to the decoupling layer, wherein the semiconductor chip is embedded in the encapsulation.

14. The method according to claim 13, wherein the decoupling layer is produced by a dispenser.

15. (canceled)

16. A component with an optoelectronic semiconductor chip fixed to a connection carrier by a bonding layer and embedded in an encapsulation, wherein a decoupling layer is arranged at least in places between the bonding layer and the encapsulation; the decoupling layer has a modulus of elasticity of at most 1 GPa; and the semiconductor chip projects beyond the decoupling layer in a vertical direction.
